(19) United States
(12) Patent Application Publication
(10) Pub. No.: US 2009/0229972 A1
(43) Pub. Date: Sep. 17, 2009

(54) METHOD AND APPARATUS FOR PRODUCING A FEATURE HAVING A SURFACE ROUGHNESS IN A SUBSTRATE

(76) Inventors: R. Mohan Sankaran, University Heights, OH (US); R. Craig Virnelson, Chesterland, OH (US)

Correspondence Address: BRINKS HOFER GILSON & LIONE, P.O. BOX 10395, CHICAGO, IL, 60610, US

(21) Appl. No.: 12/403,055

(22) Filed: Mar. 12, 2009

Related U.S. Application Data
(60) Provisional application No. 61/036,297, filed on Mar. 13, 2008.

(51) Int. Cl. C23C 14/00; H05H 1/24

(52) U.S. Cl. 204/192.32; 204/298.31

(57) ABSTRACT

An apparatus for producing features having a surface roughness in a substrate includes, according to one embodiment, a conductive first electrode disposed in opposition to a conductive second electrode, where the first and second electrodes are spaced apart from each other by a distance adapted for generating a microplasma therebetween. The second electrode is a substrate, and the first electrode and the substrate are configured for relative motion in at least two opposing directions. A feature comprising a surface roughness of greater than about 10 nm is formed in the substrate when the microplasma is generated. Preferably the feature has a width of about 300 nm or less. A plurality of the features (e.g., an ordered array of features) may be produced in the substrate, if desired. The substrate may be a silver-coated glass substrate used for surface-enhanced Raman scattering (SERS) analysis of biochemical molecules.

### RELATED APPLICATION

The present patent document claims the benefit of the filing date under 35 U.S.C. §119(e) of U.S. Provisional Patent Application Ser. No. 61/036,297, which was filed on Mar. 13, 2008, and is hereby incorporated by reference in its entirety.

### TECHNICAL FIELD

The present disclosure relates generally to surface modification technology, and more particularly to a method and apparatus for producing a feature having a surface roughness in a substrate.

### BACKGROUND

Plasmas can be generally described as ionized gases that are employed industrially for materials processing. For example, in the microelectronics industry, plasmas have been implemented in the transfer of fine patterns to a substrate surface for device fabrication by the combination of lithography followed by dry etching. Conventional lithography generally employs a resist mask formed through a series of processes, such as spin coating of a resist film, the soft and hard baking of the film, exposure of the film to photons, electrons, or ion beams, and finally the development of the film. The processes related to the resist mask and vacuum set-up may constitute a substantial portion of the device production cost. Moreover, the use of resist masks imposes limitations on the resulting etch profile, the etch selectivity, and the substrate geometry that may be employed for patterning.

### BRIEF SUMMARY

A microplasma-based method and apparatus for producing a feature having a surface roughness in a substrate are described herein. Preferably, the feature has a roughness of about 10 nm or greater and a width of about 300 nm or less. A plurality of the features (e.g., an ordered array of such features) may be produced in the substrate, if desired. The substrate including the one or more features may be suited for use as a substrate in surface-enhanced Raman scattering (SERS) analysis of biochemical substances.

According to a first embodiment, the apparatus includes a conductive first electrode disposed in opposition to a conductive second electrode, where the first and second electrodes are spaced apart from each other by a distance adapted for generating a microplasma therebetween. The second electrode is a substrate, and the first electrode and the substrate are configured for relative motion in at least two opposing directions. A feature comprising a surface roughness of greater than about 10 nm is formed in the substrate when the microplasma is generated.

According to a second embodiment, the apparatus includes a conductive first electrode disposed in opposition to a conductive second electrode, where the first and second electrodes are spaced apart from each other by a distance adapted for generating a microplasma therebetween, and also a stage configured to provide relative motion of the first and second electrodes in at least two opposing directions. A feature comprising a surface roughness of greater than about 10 nm is formed in a substrate when the microplasma is generated. The relative motion of the first and second electrodes allows an array of the features to be formed.

According to a third embodiment, the apparatus includes a conductive hollow electrode including a cavity extending therethrough from a first opening to a second opening, and a conductive counter electrode disposed in opposition to the conductive hollow electrode, where the counter electrode is spaced apart from the second opening of the hollow electrode by a distance adapted for generating a microplasma therebetween. A feature having a surface roughness of greater than about 10 nm is formed in the counter electrode when the microplasma is generated.

According to a fourth embodiment, the apparatus includes: a conductive hollow electrode including a cavity extending therethrough from a first opening to a second opening; a conductive counter electrode disposed in opposition to the conductive hollow electrode, where the conductive counter electrode is spaced apart from the second opening of the hollow electrode by a distance adapted for generating a microplasma therebetween; and also a stage configured to provide relative motion of the hollow electrode and the counter electrode in a direction parallel to a surface of the counter electrode. A feature comprising a surface roughness of greater than about 10 nm is formed in the counter electrode when the microplasma is generated. The relative motion of the hollow electrode and the counter electrode allows a plurality of the features to be formed in the counter electrode.

According to a first embodiment, the method includes generating a microplasma between a conductive first electrode and a conductive second electrode, where the first and second electrodes are spaced apart a distance adapted for generating a microplasma therebetween and the second electrode is a substrate, and forming a feature in the substrate, the feature comprising a surface roughness of greater than about 10 nm and having a lateral dimension of about 300 microns or less.

According to a second embodiment, the method includes: generating a microplasma between a conductive first electrode and a conductive second electrode, where the first and second electrodes are spaced apart a distance adapted for generating a microplasma therebetween and the second electrode is a substrate; forming a feature in the substrate, where the feature has a surface roughness of greater than about 10 nm; inducing relative motion of the first and second electrodes in a direction parallel to a surface of the substrate so that the first and second electrodes take on a new relative position; generating a microplasma between the first and second electrodes at the new relative position; and forming a new feature in the substrate, where the new feature has a surface roughness of greater than about 10 nm. Preferably, moving to the new relative position and generating the microplasma between the hollow electrode and counter electrode are carried out multiple times to form an array of features in the substrate.

According to a third embodiment, the method includes: providing a conductive hollow electrode including a cavity extending therethrough from a first opening to a second opening; providing a conductive counter electrode in opposition to the conductive hollow electrode, where the counter electrode is spaced apart from the second opening of the hollow electrode by a distance adapted for generating a microplasma therebetween; generating a microplasma between the second opening of the hollow electrode and the counter electrode; and forming a feature in the counter electrode, where the feature has a surface roughness of greater than about 10 nm, thereby producing a substrate for surface-enhanced Raman scattering.

According to a fourth embodiment, the method includes: providing a conductive hollow electrode including a cavity extending therethrough from a first opening to a second opening; providing a conductive counter electrode in opposition to the conductive hollow electrode, where the counter electrode is spaced apart from the second opening of the hollow electrode by a distance adapted for generating a microplasma therebetween; generating a microplasma between the hollow electrode and the counter electrode at the first position; forming a feature in the counter electrode, the feature comprising a surface roughness of greater than about 10 nm; inducing relative motion of the hollow electrode and the counter electrode in a direction parallel to a surface of the counter electrode so that the hollow electrode and the counter electrode take on a new relative position; generating a microplasma between the hollow electrode and the counter electrode at the new relative position; and forming a new feature in the counter electrode, where the new feature has a surface roughness of greater than about 10 nm. Preferably, moving to the new relative position and generating the microplasma between the hollow electrode and counter electrode are carried out multiple times to form a plurality of features in the counter electrode, thereby producing a substrate for surface-enhanced Raman scattering.

### BRIEF DESCRIPTION OF THE DRAWINGS

FIG. 1 is a schematic of a microplasma apparatus according to one embodiment;

FIGS. 2A and 2B are scanning electron microscopy (SEM) images of portions of a four-hole array produced using the microplasma apparatus of FIG. 1;

FIG. 2C is a collection of atomic force microscopy (AFM) images taken from different portions of the substrate shown in the central (SEM) image;

FIGS. 3A and 3B are surface-enhanced Raman scattering (SERS) spectra obtained from crystal violet (CV) on patterned and bare substrates (FIG. 3A) and on patterned substrates at various concentrations (FIG. 3B); and

FIG. 4 is a SERS intensity map obtained from single hole produced using the microplasma apparatus of FIG. 1.

### DETAILED DESCRIPTION

A nonlithographic, direct patterning process based on a rastered, atmospheric pressure microplasma source is described herein for producing one or more features having a surface roughness in a substrate. The process is believed to be particularly suitable for the fabrication of low-cost, sensitive, highly reproducible, and stable substrates for surface-enhanced Raman scattering (SERS). Direct patterning using a microplasma may eliminate the need for resist masks, which are generally expensive to fabricate. Although conventional lithographic methods may be capable of producing smaller feature sizes than microplasmas, the inventors have recognized that the latter may be sufficient and advantageous for SERS-active substrate fabrication, where larger structures have been shown to exhibit significant enhancement factors.

According to a preferred embodiment, a metallic thin film (e.g., silver (Ag) supported on glass) is patterned using an argon (Ar) microplasma source coupled with a numerically controlled stage. Localized physical sputtering of the metallic film by the microplasma creates depressions or other localized features that may amplify the Raman scattering intensities from a test molecule (e.g., crystal violet (CV)) by a factor of 10⁸-10¹⁰. Raman spectra of CV deposited in the features can be detected down to picomolar concentration levels on patterned Ag/glass substrates, indicating a significant enhancement over bare substrates.

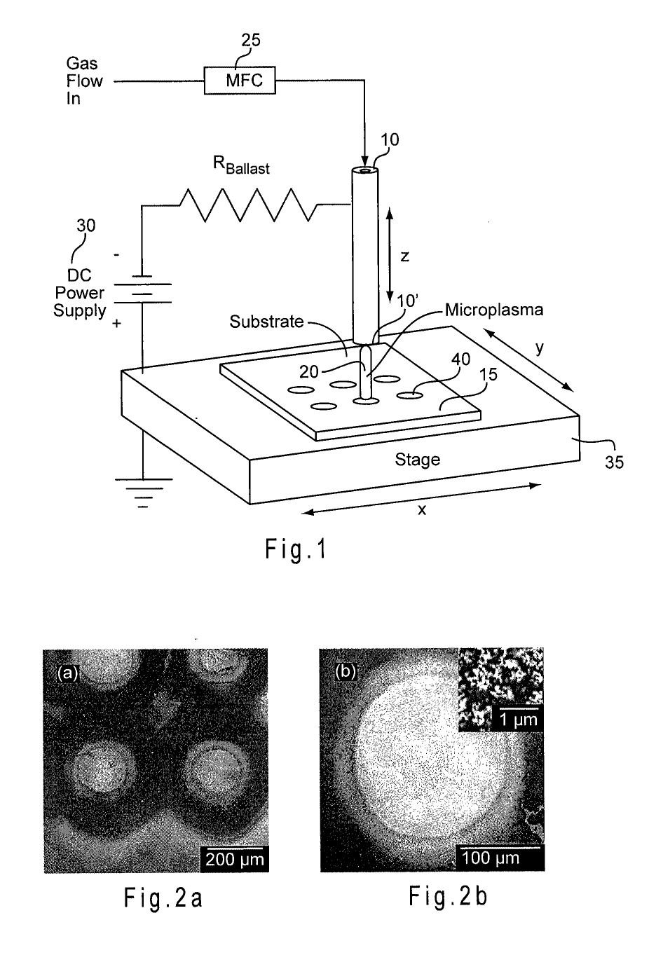

A schematic of the setup used for nonlithographic pattern transfer is illustrated in FIG. 1. The patterning tool includes an atmospheric-pressure microplasma source formed between a metallic (e.g., stainless-steel) capillary tube 10 and a conductive substrate 15, which serve as a hollow cathode and an anode (or counter electrode), respectively. To obtain hollow cathode operation at high pressures, such as at atmospheric pressure, the inner diameter of the capillary tube 10 is preferably about 250 microns or less. According to one embodiment, the capillary tube 10 has an inner diameter in the range of from about 100 to about 200 microns. The capillary tube 10 generally has a substantially uniform diameter along the length of the tube.

An inert gas such as argon or helium is flowed through the capillary tube 10 at a rate of between about 100-500 SCCM, where SCCM denotes cubic centimeters per minute at standard temperature and pressure (STP). One or more reactive gases may also be employed. In a typical experiment, a microplasma 20 is formed at ambient conditions with an argon gas flow rate of about 500 SCCM, which is set by a mass flow controller 25. Typically, a negatively biased DC power supply (e.g., Keithley, Inc. model 246) 30 operates the discharge with a current-limiting resistor in series with the microplasma 20. A voltage of 400 V and a current of 5 mA, for example, are suitable for generating the microplasma 20. The microplasma 20 extends from the capillary tube opening 10′ in a direction perpendicular to a grounded substrate 15, which may be, for example, a conductive silver-coated glass slide obtained from Kevley, Inc. The distance between the capillary tube 10 and the substrate 15 is typically about 6 mm or less, and may be about 2.5 mm or less. U.S. Pat. No. 6,700,329, which is hereby incorporated by reference in its entirety, discloses details related to such microplasma sources and their use in generating microdischarges.

The hollow cathode 10 and the substrate 15 are configured for relative motion in at least two opposing directions. The substrate 15 may be attached to a stage 35 controlled by a pair of numerically controlled stepper motors to provide motion in the x- and y-directions, as shown in FIG. 1. Movement in the z-direction may be achieved by a third stepper motor which controls the distance between the plasma source and the substrate. According to the embodiment of FIG. 1, the substrate 15 moves, and the hollow cathode (capillary tube) 10 remains stationary. Alternatively, the hollow cathode may be attached to the movable stage so that it moves horizontally or vertically, while the substrate remains stationary. Commercially available LABVIEW software may be utilized for horizontal scanning.

During microplasma generation, a feature (e.g., a depression having a particular depth) 40 is formed in the silver film through Ar ion and neutral collisions with the substrate surface that result in sputtering of the silver atoms. Generally, the feature 40 may be formed in a single location after about two to about eight minutes of sputtering. For example, the feature 40 may be formed after about four to about six minutes of sputtering. The depth of the feature (depression) 40 may be controlled by the duration of sputtering. The feature may extend partway or entirely through the metal film.

The feature may be a discrete or continuous structure, such as an indentation, hole, line or curve. Preferably, the feature is a localized feature having an average width of about 500 microns or less. For example, the average width of the feature may range from about 50 microns to about 500 microns. More preferably, the average width of the feature is about 300 microns or less. Even more preferably, the average width is about 200 microns or less, and may be about 100 microns or less. According to one embodiment, the average width is in the range of from about 100 microns to about 200 microns. In the case of an indentation or a hole, the width of the feature may correspond to a diameter. A continuous feature (e.g., a line or curve) may have a length that is considerably larger than its width. For example, lines or curves of millimeters or centimeters in length may be fabricated using the microplasma apparatus described herein. Such features are obtained by moving the substrate in the x and/or y direction while the plasma is being generated.

Surprisingly, the feature contains nanoscale bumps or irregularities and thus has a measurable surface roughness. The inventors believe the surface roughness may be advantageous for SERS analysis. Preferably, the surface roughness of the feature is greater than about 10 nm, on average. For example, the average surface roughness may be about 20 nm or greater, or about 50 nm or greater. The feature may also show surface roughness on the microscale (e.g., about 100 nm or greater). For the fabrication of SERS substrates, it may be advantageous for the surface roughness to be about 100 nm or less, on average. According to several embodiments, the average surface roughness of the feature may range from about 10 nm to about 300 nm, from about 30 nm to about 150 nm, or from about 50 nm to 100 nm. The inventors believe that the surface roughness may be created by the redeposition of sputtered material in the feature during microplasma generation.

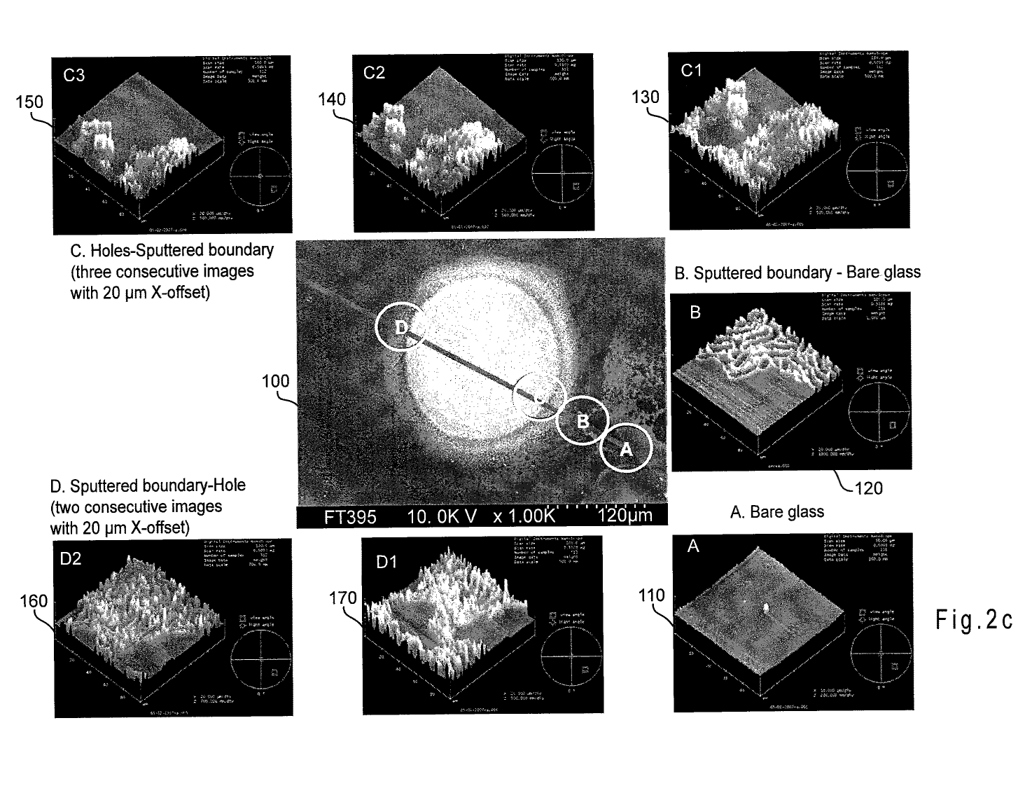

More than one feature may be formed in the substrate. According to one embodiment, a plurality of the features may be formed. The features may be arranged in a regular array, as shown for example in FIG. 2A. By fabricating a regular array including a large number of features, SERS substrates may be produced in high volumes.

It is of interest to correlate the morphology (e.g., surface roughness) of silver films including the above-described features with SERS signal enhancement. Raman spectroscopy is a label-free optical detection technique for chemicals and biomolecules. A Raman spectrum provides an optical fingerprint of chemicals and biomolecules, although conventional Raman detection is limited by extremely low efficiency of scattering. In surface enhanced Raman scattering (SERS), the surface area of the substrate is increased and thus the optical cross-section for scattering increases. A discussion of SERS can be found in M. Moskovits, “Surface-Enhanced Spectroscopy,” Reviews of Modern Physics, 1985, vol. 57, pp. 783-826, which is hereby incorporated by reference in its entirety. Traditionally, SERS substrates have been based on colloidal silver or gold nanoparticles or thin films deposited on silicon or polymer substrates.

FIG. 2A is a scanning electron microscopy (SEM) image of a substrate that has been patterned with an array of four holes, each sputtered for 5 min, with a center-to-center distance of 400 microns. FIG. 2B is a close-up view of a single hole. The overall morphology of each hole shows Ag sputtered over a diameter of approximately 200 microns. The radial profile of the patterned structures is consistent with previous results where a higher concentration of excited states have been found along the center line of the microplasma source. Surface irregularities made up of aggregated particles with a diameter of approximately 100 nm are visible inside the sputtered region. Energy dispersive spectroscopy (EDS) was used to confirm that the observed surface moieties are composed of Ag.

FIG. 2C shows atomic force microscopy (AFM) images of different portions of the substrate shown in the central SEM image 100: (A) bare glass 110; (B) sputtered boundary-bare glass 120; (C) hole-sputtered boundary (three consecutive images with a 20 micron x-offset) 130, 140, 150; (D) sputtered boundary-hole (two consecutive images with a 20 micron x-offset) 160, 170. The AFM images show nanoscale and microscale surface roughness in the sputtered regions.

Micro-Raman spectroscopy was performed at room temperature using a Jobin-Yvon Horiba LabRam system with a He—Ne laser with an excitation frequency of 633 nm. CV 10B dissolved in methanol was used as a test molecule. Solutions were placed on the substrates in a 200 micron-thick well covered by a glass cover slip to prevent solvent evaporation. To obtain spectra, a 17 mW laser beam with a 2 micron spot size and 4 micron depth of field was passed through the cover slip and focused on the substrate surface. For the patterned samples, Raman spectra were acquired from different spots in the sputtered hole.

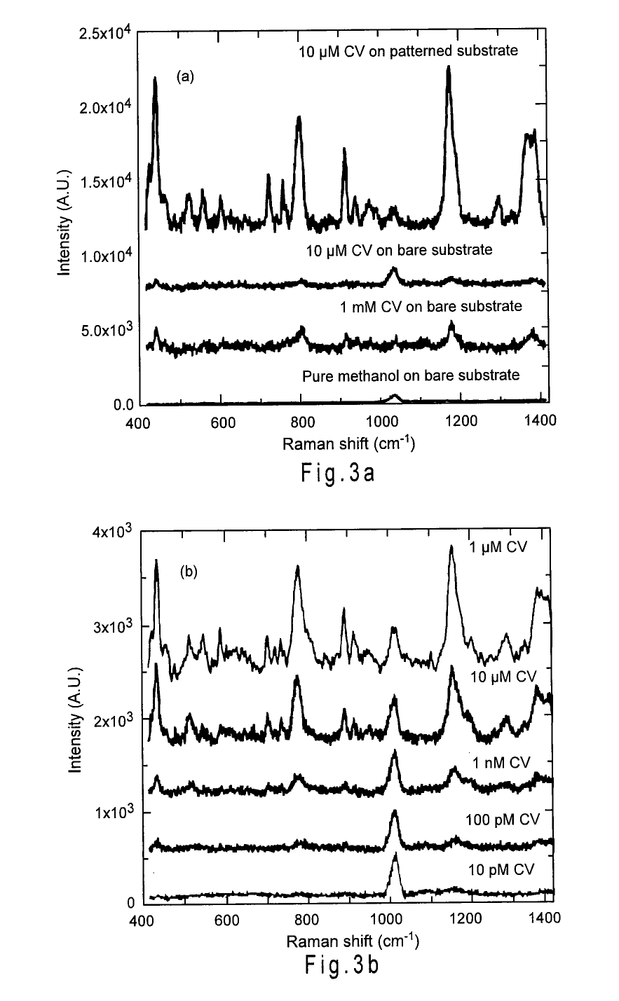

FIG. 3A shows typical Raman spectra obtained for dilute methanolic solutions of CV (10⁻⁵M) on patterned and bare Ag/glass substrates. The patterned substrate exhibits strong enhancement of almost all of the characteristic Raman peaks for CV including the peaks centered at approximately 441, 799, 916, 1176, and 1376 cm⁻¹. The spectrum for a bare substrate shows few visible signals except the methanol-related peak centered at 1035 cm⁻¹. For illustrative purposes, spectra for pure methanol and a higher concentration of CV (10⁻³M) on bare Ag/glass substrates are also included.

Since the SERS enhancement is not a linear process, the enhancement factor is estimated by comparing the Raman scattering intensities of the methanol peak at 1035 cm⁻¹ and a CV peak at 1176 cm⁻¹. The SERS enhancement factor can be calculated from the ratio of (I_{CV}/N_{CV})/(I_{MeOH}/N_{meOH}), where I_{CV} and I_{MeOH} denote the integrated intensities of the bands for CV and methanol, respectively, and N_{CV} and N_{MeOH} represent the corresponding number of CV and methanol molecules excited by the laser beam. It is assumed that all methanol molecules from the probed volume, defined by a diameter equal to the beam spot size and length equal to the depth of field, contribute to the methanol Raman peak, while CV molecules from only a thin layer of thickness near the substrate surface, approximated to be between 10 nm and 300 nm, contribute to the SERS signal. Based on this approach and the data in FIG. 3A, enhancement factors of 10⁸-10¹⁰ can be calculated.

To detect varying concentrations of CV, a series of solutions was introduced on the same substrate with thorough washing by methanol between loadings. The Raman spectra in FIG. 3B show discernible peaks down to a concentration of 100 pM CV. For the lowest concentration of 10 pM CV, only the 1176 cm⁻¹ is barely visible.

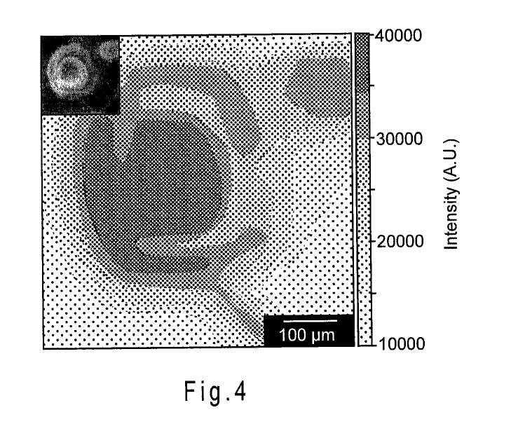

The existence of “hot spots” or variation in the SERS enhancement on a patterned substrate was determined by scanning the laser beam over an area of 300×300 square microns in 10 micron steps to obtain intensity maps. A false color SERS intensity map for a sputtered hole is shown in FIG. 4. The color is proportional to the integrated intensity of the CV Raman band centered at 1176 cm⁻¹. FIG. 4 reveals that the strongest SERS enhancement is observed inside the sputtered holes and remains relatively constant over the hole area. Remarkably, the SERS enhancement closely follows the morphology created by the patterning process (see inset of FIG. 4). Based on the microstructural characterization, the inventors attribute the SERS enhancement in the hole region to sputtering and redeposition of Ag which produce surface irregularities that appear to be small particles and aggregates.

The inventors have developed a simple and reproducible method to fabricate SERS-active substrates by nonlithographic patterning using a numerically-controlled tool for generating a microplasma. The tool enables microscale features, such as arrays of holes, to be carved into metal (e.g., silver) films, thus dramatically altering the density of SERS-active sites in the films. The technique is scalable and may allow mass production of identical SERS substrates for a wide array of chemical, biomedical, and environmental applications.

Although the present invention has been described in considerable detail with reference to certain embodiments thereof, other embodiments are possible without departing from the present invention. The spirit and scope of the appended claims should not be limited, therefore, to the description of the preferred embodiments contained herein. All embodiments that come within the meaning of the claims, either literally or by equivalence, are intended to be embraced therein. Furthermore, the advantages described above are not necessarily the only advantages of the invention, and it is not necessarily expected that all of the described advantages will be achieved with every embodiment of the invention.

1. An apparatus for producing a substrate including a feature having a surface roughness, the apparatus comprising:
a conductive first electrode disposed in opposition to a conductive second electrode, the first and second electrodes being spaced apart from each other by a distance adapted for generating a microplasma therebetween, the second electrode being a substrate,
wherein a feature comprising a surface roughness of greater than about 10 nm is formed in the substrate when the microplasma is generated, and
wherein the first electrode and the substrate are configured for relative motion in at least two opposing directions.

2. The apparatus of claim 1, wherein the feature is a depression in the substrate.

3. The apparatus of claim 2, wherein the substrate includes a silver film.

4. The apparatus of claim 1, wherein the distance between the first and second electrodes is about 6 mm or less.

5. The apparatus of claim 1, wherein the first electrode is a hollow electrode including a cavity extending therethrough from a first opening to a second opening, the second opening being closer than the first opening to the second electrode.

6. The apparatus of claim 5, wherein the distance between the second opening of the hollow electrode and the second electrode is about 6 mm or less.

7. The apparatus of claim 6, wherein the distance between the second opening of the hollow electrode and the second electrode is about 2.5 mm or less.

8. The apparatus of claim 5, wherein the first opening of the hollow electrode comprises a gas inlet to the cavity.

9. The apparatus of claim 5, wherein the cavity has a diameter of about 200 microns or less.

10. The apparatus of claim 1, wherein at least one of the two opposing directions is parallel to a surface of the second electrode.

11. The apparatus of claim 1, further comprising a computer-controlled stage configured to induce the relative motion of the first and second electrodes in the at least two opposing directions.

12. The apparatus of claim 11, wherein the stage is attached to the second electrode to induce motion of the second electrode.

13. The apparatus of claim 1, wherein the relative motion of the first and second electrodes allows a plurality of the features to be formed in the substrate.

14. The apparatus of claim 13, wherein the plurality of features are arranged in a regular array.

15. The apparatus of claim 1, wherein the substrate is a surface-enhanced Raman scattering (SERS) substrate.

16. A method for producing a substrate including a feature having a surface roughness, the method comprising:
providing a conductive hollow electrode including a cavity extending therethrough from a first opening to a second opening;
providing a conductive counter electrode in opposition to the conductive hollow electrode, the counter electrode being spaced apart from the second opening of the hollow electrode by a distance adapted for generating a microplasma therebetween;
generating a microplasma between the second opening of the hollow electrode and the counter electrode;
forming a feature in the counter electrode, the feature comprising a surface roughness of greater than about 10 nm, thereby producing the substrate.

17. The method of claim 16, wherein generating the microplasma comprises introducing a gas into the cavity through the first opening and applying a voltage across the hollow electrode and the counter electrode.

18. The method of claim 17, wherein applying the voltage comprises applying a dc voltage in the range of from ±(250 V to 750 V).

19. The method of claim 17, wherein applying the voltage comprises grounding the counter electrode and applying a negative voltage to the hollow electrode.

20. The method of claim 17, wherein the gas flows through the cavity at a rate in the range of from about 300 SCCM to about 500 SCCM.

21. The method of claim 16, wherein the microplasma is generated in an atmospheric pressure environment.

22. The method of claim 16, wherein forming the feature comprises sputtering material from the counter electrode by way of the plasma, at least some of the material being redeposited in the feature to create the surface roughness.

23. The method of claim 16, wherein forming the feature is carried out for a time duration of from about 2 minutes to about 8 minutes.

24. The method of claim 23, wherein the time duration is from about 4 minutes to about 6 minutes.

25. The method of claim 16, wherein the feature has an average width in the range of from about 50 microns to about 500 microns.

26. The method of claim 25, wherein the average width is in the range of from about 100 microns to about 200 microns.

27. The method of claim 16, wherein the feature is a depression in the counter electrode.

28. The method of claim 16, further comprising inducing relative motion of the hollow electrode and the counter electrode in a direction parallel to a surface of the counter electrode.

29. The method of claim 28, wherein inducing the relative motion of the hollow cathode and the counter electrode comprises utilizing a computer-controlled stage attached to the counter electrode to move the counter electrode.

30. The method of claim 28, further comprising generating the microplasma multiple times to form a plurality of features in the counter electrode.

31. The method of claim 30, wherein the plurality of features are formed in a regular array.
